(19) United States
(12) Patent Application Publication
(10) Pub. No.: US 2024/0318040 A1
(43) Pub. Date: Sep. 26, 2024

(54) CHEMICAL MECHANICAL POLISHING SLURRY COMPOSITION AND METHOD OF MANUFACTURING SEMICONDUCTOR DEVICE USING THE SAME

(71) Applicant: Samsung Electronics Co., Ltd., Suwon-si (KR)

(72) Inventors: Yearin Byun, Suwon-si (KR); Jeongwon Lim, Suwon-si (KR); Boyun Kim, Suwon-si (KR); Sanghyun Park, Suwon-si (KR); Seungho Park, Suwon-si (KR)

(21) Appl. No.: 18/609,533

(22) Filed: Mar. 19, 2024

(30) Foreign Application Priority Data
Mar. 24, 2023 (KR) 10-2023-0039216
May 25, 2023 (KR) 10-2023-0067730

(51) Int. Cl. C09G 1/04; H01L 21/3205; H01L 21/321

(52) U.S. Cl. CPC C09G 1/04; H01L 21/3212; H01L 21/32051

(57) ABSTRACT

Provided is a chemical mechanical polishing (CMP) slurry composition including an organic booster including an amino acid, a pH adjuster, and inorganic abrasive particles of less than 0.1 weight % with respect to a total weight of the CMP slurry composition, wherein a material constituting a remaining part of the CMP slurry composition is deionized water (DIW).

### CROSS-REFERENCE TO RELATED APPLICATIONS

This application claims priority under 35 U.S.C. § 119 to Korean Patent Application Nos. 10-2023-0039216, filed on Mar. 24, 2023, and 10-2023-0067730, filed on May 25, 2023, in the Korean Intellectual Property Office, the disclosures of which are incorporated by reference herein in their entirety.

### BACKGROUND

The inventive concept relates to a chemical mechanical polishing slurry composition and a method of manufacturing a semiconductor device using the same, and more particularly, to a chemical mechanical polishing slurry for chemical mechanical polishing a metal layer and a method of manufacturing a semiconductor device using the same.

As the degree of integration of a semiconductor device or an integrated circuit device increases, a multi-layer wiring structure interconnecting functional elements like transistors, capacitors, and resistors to one another is used. To manufacture a semiconductor device including a multi-layer wiring structure, a chemical mechanical polishing process of planarizing a metal layer is essential. A chemical mechanical polishing slurry may be used for a chemical mechanical polishing process of the metal layer.

### SUMMARY

The inventive concept provides a chemical mechanical polishing (CMP) slurry composition capable of improving planarity of a metal layer and reducing the time for CMP of a metal layer.

The inventive concept also provides a method of manufacturing a semiconductor device including a CMP operation using the CMP slurry composition.

In addition, the technical goals to be achieved by the inventive concept are not limited to the technical goals mentioned above, and other technical goals may be clearly understood by one of ordinary skill in the art from the following descriptions.

The inventive concept provides a chemical mechanical polishing (CMP) slurry composition as follows.

According to an aspect of the inventive concept, there is provided a chemical mechanical polishing (CMP) slurry composition including an organic booster including an amino acid, a pH adjuster, and inorganic abrasive particles of less than 0.1 weight % with respect to a total weight of the CMP slurry composition, wherein a material constituting a remaining part of the CMP slurry composition is deionized water (DIW).

According to another aspect of the inventive concept, there is provided a chemical mechanical polishing (CMP) slurry composition including deionized water (DIW), an organic booster including an amino acid, and a pH adjuster, wherein the CMP slurry composition is substantially free of inorganic abrasive particles.

The inventive concept provides a method of manufacturing a semiconductor device as follows.

According to another aspect of the inventive concept, there is provided a method of manufacturing a semiconductor device, the method including forming, on a substrate, an insulation pattern, or a plurality of insulation patterns, comprising a plurality of openings spaced apart from one another in a horizontal direction, forming a metal layer in the plurality of openings of the insulation patterns (e.g., sufficiently filling the plurality of openings), and chemical mechanical polishing the metal layer on a polishing pad by using a chemical mechanical polishing (CMP) slurry composition by using the insulation pattern as a polishing stop film, wherein the CMP slurry composition includes an organic booster containing an amino acid, a pH adjuster, and inorganic abrasive particles of less than 0.1 weight % with respect to a total weight of the CMP slurry composition, and a material constituting a remaining portion of the CMP slurry composition is deionized water (DIW).

### BRIEF DESCRIPTION OF THE DRAWINGS

Embodiments of the inventive concept will be more clearly understood from the following detailed description taken in conjunction with the accompanying drawings in which:

FIG. 1 is a perspective view conceptually showing a polishing apparatus capable of performing chemical mechanical polishing (CMP) according to some embodiments of the present inventive concept;

FIG. 2 is a graph comparing degrees of etching Cu steps by using a CMP slurry composition according to a comparative example and a CMP slurry composition according to an experimental example embodiment of the present inventive concept, according to test times;

FIG. 3A is a graph comparing static etch rates of Cu steps according to types of an organic booster included in a CMP slurry composition according to some embodiments of the present inventive concept;

FIG. 3B is a result showing the depth of a recess that varies according to a change in the polishing time when a CMP slurry composition is used according to some embodiments of the present inventive concept;

FIGS. 4A to 4C are schematic cross-sectional views of results of forming a Cu-to-Cu bonding structure according to etching degrees of a Cu film according to some embodiments of the present inventive concept;

FIGS. 5A to 5M are side cross-sectional views sequentially showing a method of manufacturing a semiconductor device according to some embodiments of the present inventive concept; and

FIGS. 6A to 6K are side cross-sectional views sequentially showing a method of manufacturing a semiconductor device according to some embodiments of the present inventive concept.

### DETAILED DESCRIPTION

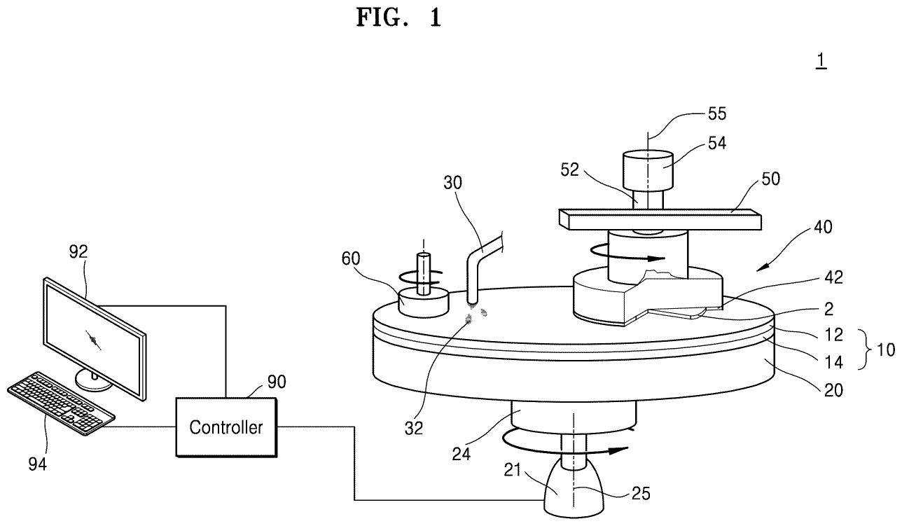

FIG. 1 is a perspective view conceptually showing a polishing apparatus 1 capable of performing chemical mechanical polishing (CMP).

Referring to FIG. 1, the polishing apparatus 1 may include a platen 20 comprising a rotary disk-like shape on which a polishing pad 10 is placed. The platen 20 may be operated to rotate around an axis 25. For example, a motor 21 may rotate a drive shaft 24 to rotate the platen 20. The polishing pad 10 may include a two or more layers including an outer polishing layer 12 and a softer backing layer 14.

The polishing apparatus 1 may include a slurry port 30 for dispensing an abrasive 32 such as a slurry onto the polishing pad 10. The polishing apparatus 1 may also include a polishing pad conditioner 60 for grinding the polishing pad 10 to maintain the polishing pad 10 in a consistent polishing condition.

The polishing apparatus 1 includes at least one carrier head 40. The carrier head 40 may be operated to hold a substrate 2 against the polishing pad 10. The carrier head 40 may control polishing parameters associated with each individual substrate, e.g., pressure.

In particular, the carrier head 40 may include a retaining ring 42 to retain the substrate 2 below a flexible membrane. The carrier head 40 may also include a plurality of independently controllable pressurizable chambers defined by the flexible membrane, wherein the plurality of pressurizable chambers may apply independently controllable pressure on related regions on the flexible membrane and related regions on the substrate 2 associated therewith.

The carrier head 40 is suspended from a support structure 50, e.g., a carousel or a track, and is connected to a carrier head rotating motor 54 through a drive shaft 52, and thus, the carrier head 40 may rotate around the axis 55. Optionally, the carrier head 40 may vibrate laterally, for example, on a slider on the carousel 50 or a track or may vibrate due to rotational vibration of the carousel 50 itself. During operation, the platen 20 is rotated around its central axis, i.e., the axis 25, and the carrier head 40 is rotated around its central axis, i.e., the axis 55, and translated laterally across the top surface of the polishing pad 10.

Although only one carrier head 40 is shown in FIG. 1, two or more carrier heads may be provided to hold additional substrates for efficient utilization of the surface area of the polishing pad 10.

The polishing apparatus 1 also includes a control system for controlling rotation of the platen 20. The control system may include a controller 90 like a general-purpose programmable digital computer, an output device 92 for output (e.g., a monitor), and an input device 94 for input (e.g., a keyboard).

Although FIG. 1 shows that the control system is connected only to the motor 21, the control system may also be connected to the carrier head 40 to adjust head pressure or a rotational speed of the carrier head 40. Furthermore, the control system may be connected to the slurry port 30 to adjust the supply of a slurry.

One embodiment of the inventive concept provides a CMP slurry composition that may be used in the polishing apparatus 1.

The CMP slurry composition may include an organic booster including an amino acid, a pH adjuster, inorganic abrasive particles comprising less than 0.1 weight % with respect to the total weight of the CMP slurry composition, and deionized water (DIW).

The pH adjuster included in the CMP slurry composition may adjust the pH concentration of the CMP slurry composition, such that the pH concentration thereof is maintained within the range from about 7 to about 9. The pH adjuster can be any composition that can alter or maintain the pH in the CMP slurry composition to the range from about 7 to about 9, and can include ammonium hydroxide, magnesium hydroxide, sodium carbonate and the like to raise the pH of the CMP slurry composition, or acids such as phosphoric, sulfuric, hydrochloric or nitric, to lower the pH of the CMP slurry composition. In some embodiment, the pH adjuster is a buffer, such as an aqueous solution of a weak acid and a conjugate base, or a weak base and a conjugate acid. Example buffers include acetates, carbonates, bicarbonates and/or hydroxides.

The organic booster included in the CMP slurry composition may be included in the composition within the range from about 10 ppm to about 20000 ppm. In some embodiments, the organic booster may be included in the composition within the range from about 10 ppm to about 18000 ppm, about 10 ppm to about 16000 ppm, about 10 ppm to about 14000 ppm, about 10 ppm to about 12000 ppm, about 10 ppm to about 10000 ppm, about 10 ppm to about 8000 ppm, about 10 ppm to about 6000 ppm, about 10 ppm to about 4000 ppm, or about 10 ppm to about 2000 ppm. In some embodiments, the organic booster may be included in the composition at less than 20000 ppm, less than 19000 ppm, less than 18000 ppm, less than 17000 ppm, less than 16000 ppm, less than 15000 ppm, less than 14000 ppm, less than 13000 ppm, less than 12000 ppm, less than 11000 ppm, less than 10000 ppm, less than 9000 ppm, less than 8000 ppm, less than 7000 ppm, less than 6000 ppm, less than 5000 ppm, less than 4000 ppm, less than 3000 ppm, less than 2000 ppm, or less than less than 1000 ppm. In some embodiments, the organic booster may be included in the composition at more than 10 ppm, more than 20 ppm, more than 30 ppm, more than 40 ppm, more than 50 ppm, more than 60 ppm, more than 70 ppm, more than 80 ppm, more than 90 ppm, more than 100 ppm, more than 150 ppm, more than 175 ppm, more than 200 ppm, more than 225 ppm, more than 250 ppm, more than 275 ppm, more than 300 ppm, more than 325 ppm, more than 350 ppm, more than 375 ppm, or more than 400 ppm. The organic booster may comprise, consist essentially of, or consist of, at least one selected from the group consisting of leucine, tryptophan, tyrosine, and phenylalanine, or a derivative thereof. The organic booster may comprise, consist essentially of, or consist of, at least two selected from the group consisting of leucine, tryptophan, tyrosine, and phenylalanine, or a derivative thereof, for example, the organic booster may comprise two or more of leucine, tryptophan, tyrosine, and phenylalanine, or a derivative thereof.

In some embodiments, the CMP polishing slurry composition may be substantially free of inorganic abrasive particles. Substantially free of inorganic abrasive particles as used herein can comprise less than 0.3 weight %, 0.25 weight %, 0.2 weight %, 0.15 weight %, 0.10 weight %, 0.05 weight %, 0.04 weight %, 0.03 weight %, 0.02 weight %, or 0.01 weight % of the total weight of the CMP slurry composition. In some embodiments, the CMP polishing slurry composition is devoid of inorganic abrasive particles.

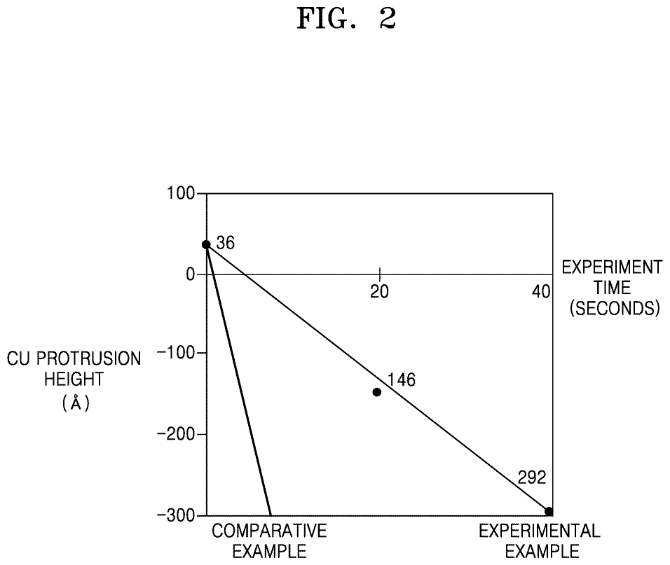

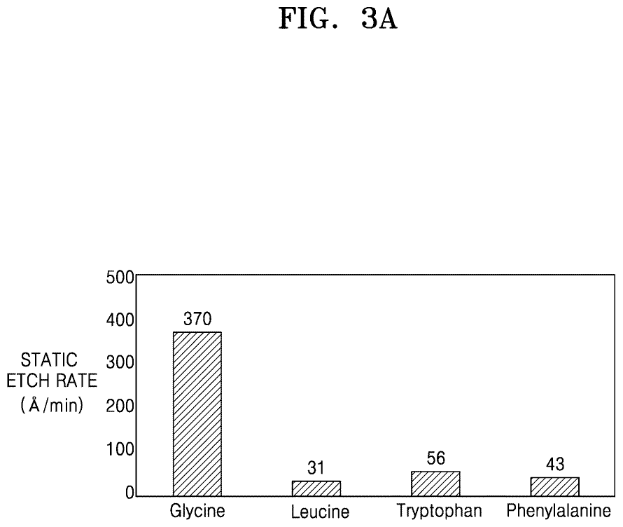

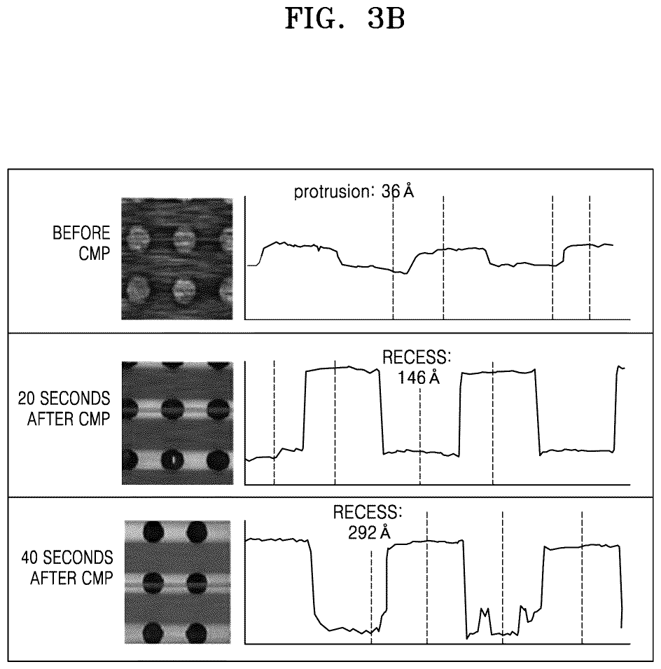

The CMP slurry composition may be used for etching protrusions of a copper (Cu) film. In this case, the height of the protrusions of the Cu film may correspond to 200 Å or less, for example, a height of 200 Å or less, 195 Å or less, 190 Å or less, 180 Å or less, 170 Å or less, 160 Å or less, 150 Å or less, 140 Å or less, 130 Å or less, 120 Å or less, 110 Å or less, or 100 Å or less relative to the metal layer, for example, a copper metal layer. The CMP slurry composition may control a static etch rate and/or a removal rate of a metal layer during a CMP process. Detailed descriptions thereof are given below with reference to FIGS. 2, 3A, and 3B together.

FIG. 2 is a graph comparing degrees of etching Cu protrusions by using a CMP slurry composition according to a comparative example and a CMP slurry composition according to an experimental example, according to test times. The CMP slurry composition according to the experimental example may include an organic booster including an amino acid, a pH adjuster, inorganic abrasive particles comprising less than 0.1 weight % with respect to the total weight of the CMP slurry composition, and DIW.

Referring to FIG. 2, it may be seen that, in contrast to the case where an initial Cu protrusion had a height of 36 Å, a Cu recess having a depth of about 146 Å was formed when 20 seconds had elapsed after the polishing process and a recess having a depth of about 292 Å was formed when the polishing time was doubled and 40 seconds had elapsed. Based on the above-stated experimental result, when a Cu film is polished by using the CMP slurry composition according to some embodiments of the inventive concept, the depth of a recess is proportional to the polishing time, and thus, it may be seen that the depth of the recess may be controlled by appropriately adjusting the polishing time. Since the CMP slurry composition according to the inventive concept enables fine control of steps (e.g., protrusions and/or recesses) of a Cu film in the unit of Å, the CMP slurry composition may be applied to various device manufacturing process including the process of polishing a Cu film.

Also, the CMP slurry composition according to the inventive concept does not need a separate inhibitor and may effectively polish a Cu film without an additional abrasive. An abrasive may cause scratches or product defects due to contamination depending on polishing conditions. Therefore, by using the CMP slurry composition according to the inventive concept, the risk of additional defects that may occur from the use of an abrasive may also be reduced. Since an abrasive is not necessary, the increased lifespan of a polishing pad and reduced cost of a slurry composition may also be expected.

FIG. 3A is a graph comparing static etch rates of Cu steps according to types of an organic booster included in a CMP slurry composition.

Referring to FIG. 3A, it may be seen that when glycine is used as an organic booster, it exhibits a higher static etch rate than when leucine, tryptophan, tyrosine, or phenylalanine is used as an organic booster. The static etch rate may be based on a result of measuring the amount of etching reduction of a Cu metal layer after etching the Cu metal layer by putting a substrate into the CMP slurry composition according to an embodiment.

Glycine corresponds to a hydrophilic amino acid, and leucine, tryptophan, tyrosine, and phenylalanine correspond to hydrophobic amino acids. Through the above-stated experimental results, it may be seen that a CMP slurry composition having a low static etch rate may be prepared when an organic booster containing a hydrophobic amino acid is used. As used herein, a “high static etch rate” achieves a depth or recess in a metal pattern in a shorter period of time relative to a low static etch rate. As an example, a high static etch rate can comprise a rate of greater than 150, 200, 250, 300, 350 or more Angstrom (Å)/min on a metal pattern. A high static etch rate can be measured relative to a low static etch rate, and may be 50%, 60%, 70%, 80%, 90%100%, 150%, 200% or more higher rate relative to a low static etch rate as measured on the same metal pattern. A low static etch rate, on the other hand, achieves a depth or recess in a metal pattern over a longer period of time relative to a high static etch rate, which can be measured, for example in Å/min on a metal pattern. As an example, a low static etch rate can comprise a rate of less than 100, 90, 80, 75, 70, 65, 60, Angstrom (Å)/min or less on a metal pattern (see, e.g., FIG. 3A).

When an organic booster having a high static etch rate is used, the depth of a recess of a metal pattern may increase, and thus, it may be difficult to control the flatness of the metal pattern. Therefore, the CMP slurry composition according to the inventive concept may facilitate adjustment of the flatness, or planarity, of a metal pattern by using an organic booster containing a hydrophobic amino acid (e.g., leucine, tryptophan, tyrosine and/or phenylalanine).

FIG. 3B is a result showing the depth of a recess that varies according to a change in the polishing time when a CMP slurry composition according to the inventive concept is used.

Referring to FIG. 3B, it may be seen that FIG. 3B corresponds to the graph shown in FIG. 2. Since the depth of a recess also increases in proportion to the increase in the polishing time, it is possible to form a recess with a desired depth without damaging the film quality of a polishing stop film by adjusting the polishing time to control recess depth.

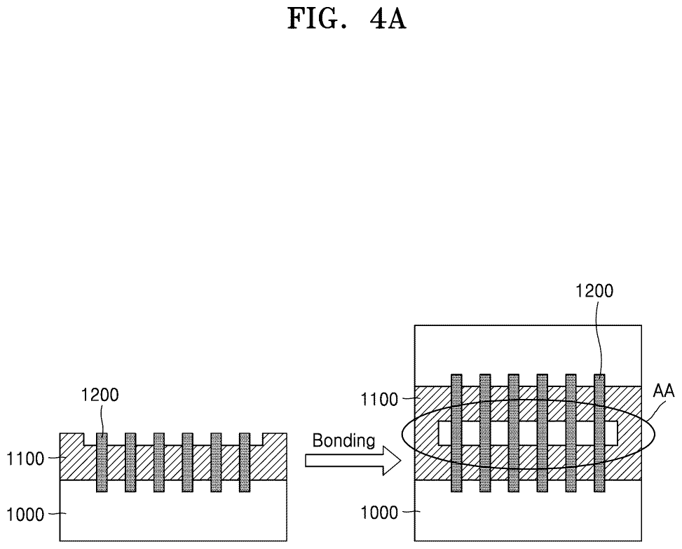

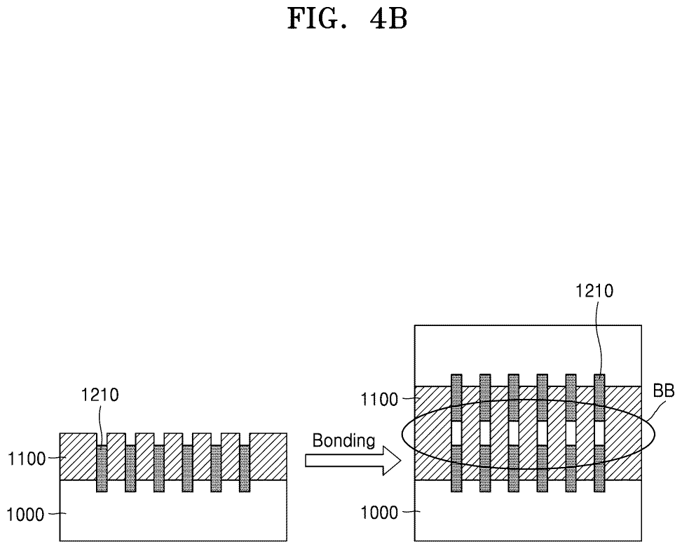

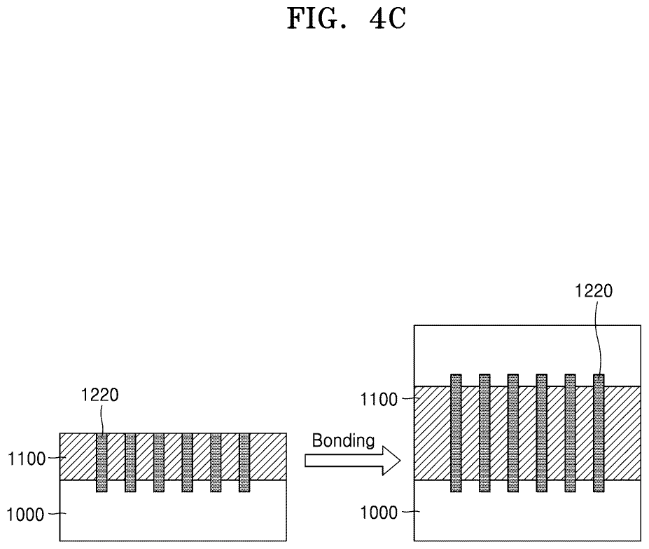

FIGS. 4A to 4C are schematic cross-sectional views of results of forming a Cu-to-Cu bonding structure according to etching degrees of a Cu film. In detail, FIG. 4A is a cross-sectional view of a result of performing Cu-to-Cu bonding in a state in which Cu film protrusions 1200 of 200 Å or less remain after a CMP process is completed. FIG. 4B is a cross-sectional view of a result of performing Cu-to-Cu bonding in a state in which an excessively deep Cu film recess 1210 is formed in the process of removing steps of a Cu film after the CMP process is completed. FIG. 4C is a cross-sectional view of a result of performing Cu-to-Cu bonding after removing a step (e.g., a protrusion) of a Cu film 1220 to an appropriate level after the CMP process is completed. In FIGS. 4A to 4C, a Cu film protrusion 1200, the Cu film recess 1210, and the Cu film 1220 formed on a substrate 1000 may each be surrounded by a low-k material 1100.

Referring to FIGS. 4A to 4C, due to an error of several A occurring in the process of etching Cu steps (e.g., protrusions and/or recesses), when Cu-to-Cu bonding is formed later, bonding may not be properly formed between low-k materials 1000 (refer to AA of FIG. 4A) or a void may be formed between Cu film recesses 1210 (refer to BB of FIG. 4B). Therefore, it may be important to etch a metal film to an appropriate level. According to a CMP slurry composition according to the inventive concept, Cu-to-Cu bonding may be stably formed by controlling the etching degree of protrusions and the depth of formed recesses through the adjustment of the polishing time (refer to FIG. 4C).

Hereinafter, a method of manufacturing a semiconductor device by using the CMP slurry composition described above is described.

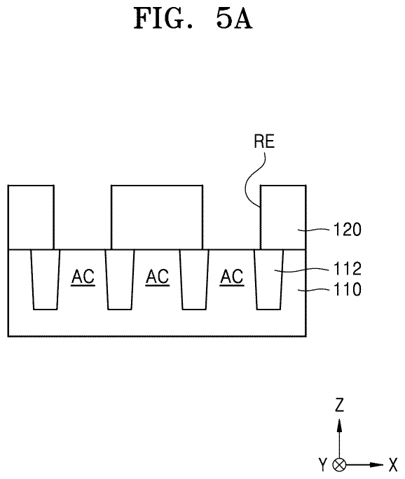

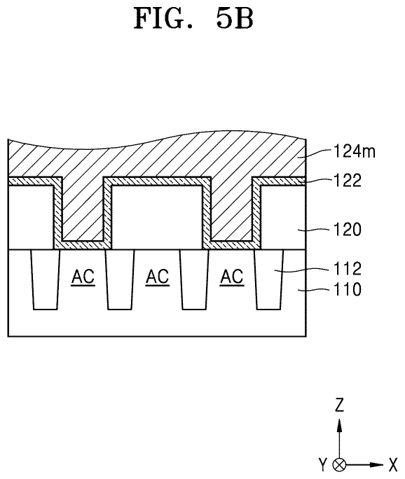

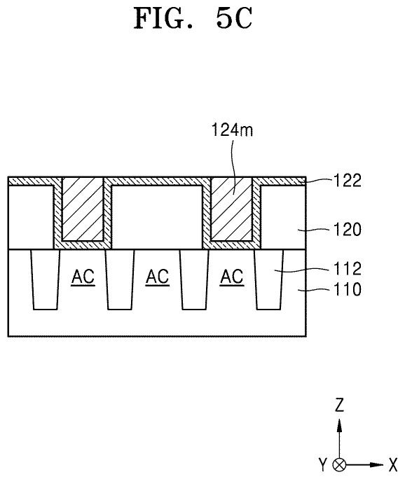

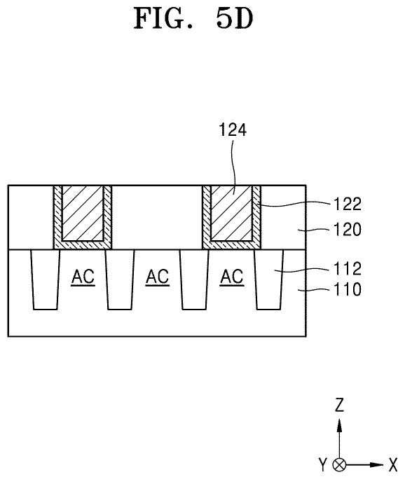

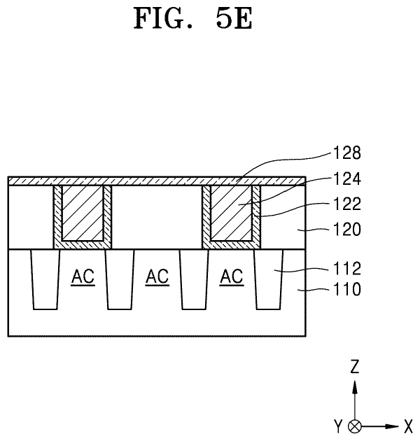

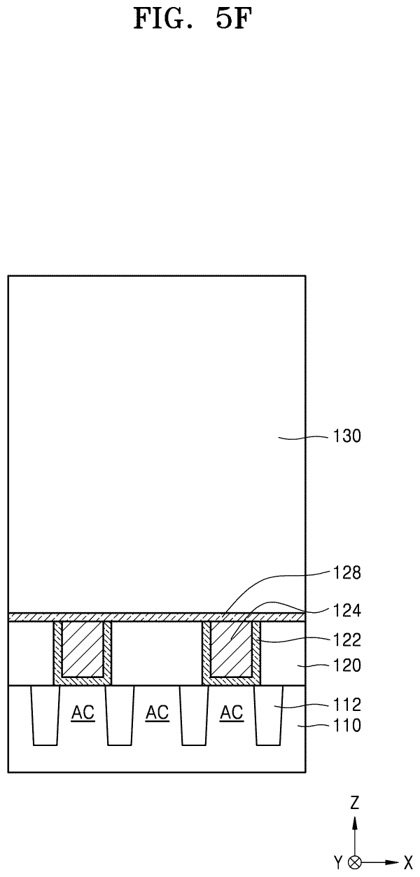

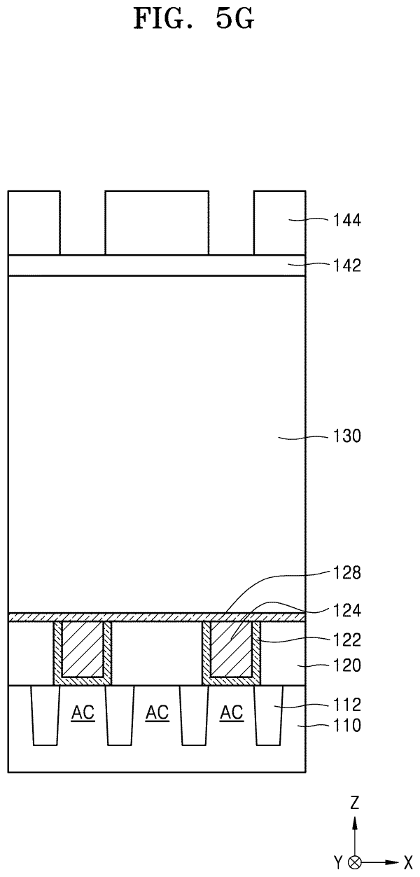

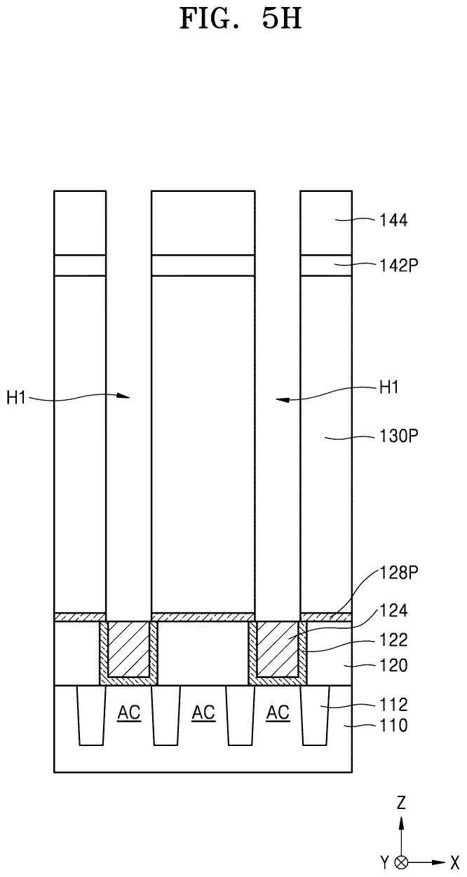

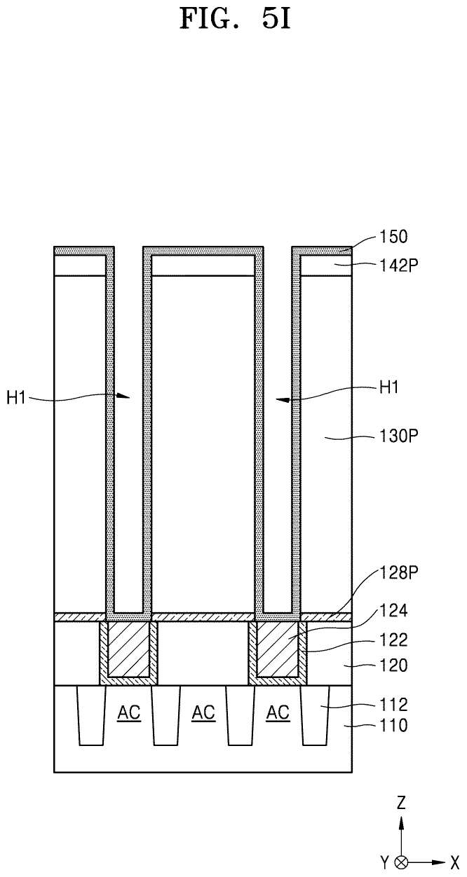

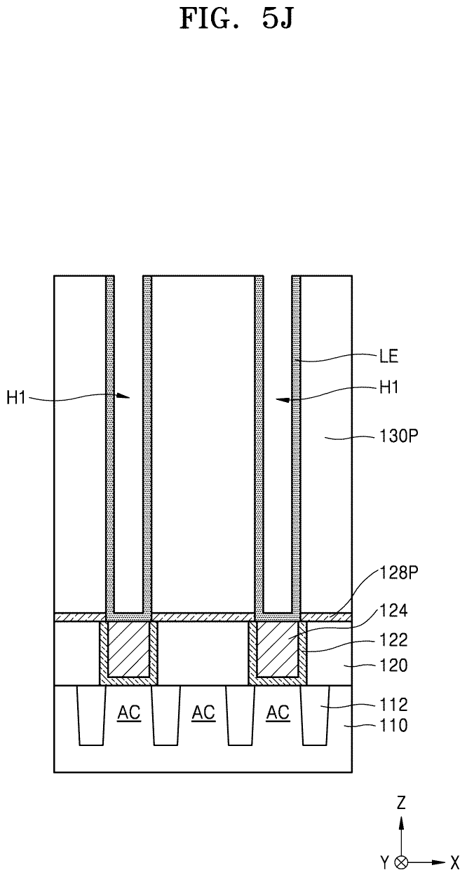

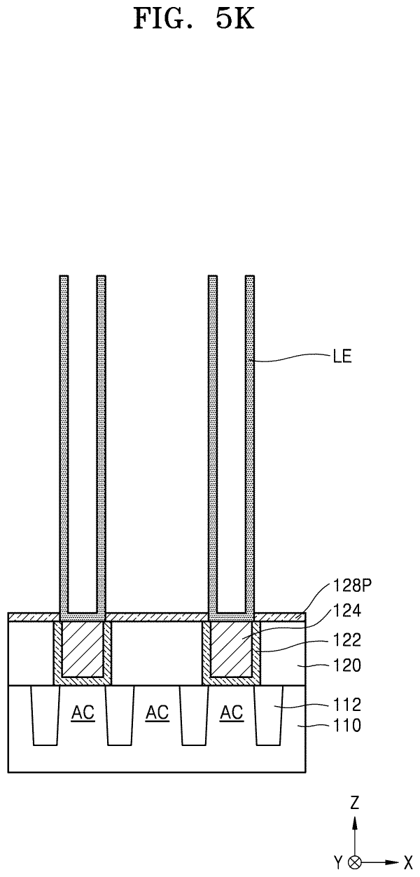

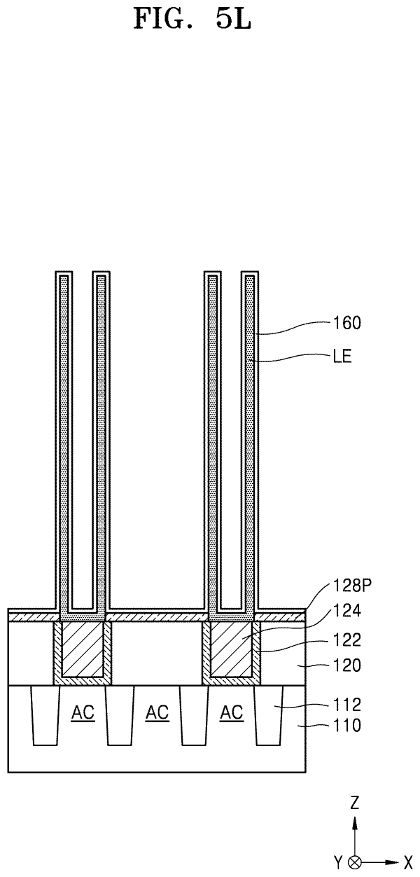

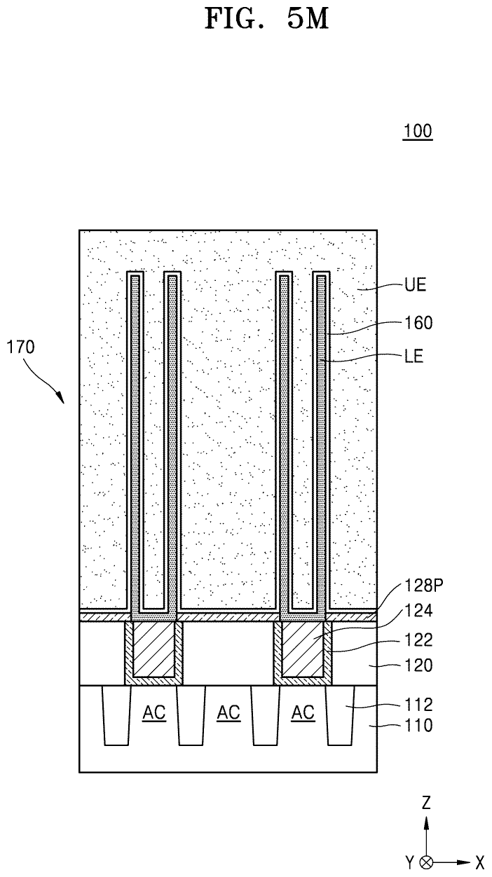

FIGS. 5A to 5M are side cross-sectional views sequentially showing a method of manufacturing a semiconductor device 100, according to an embodiment.

Referring to FIG. 5A, an interlayer insulation layer 120 patterned to at least partially expose a plurality of active regions AC may be formed on a substrate 110 including the plurality of active regions AC. The interlayer insulation layer 120 may include a recess RE exposing the active regions AC. The recess RE may be in the form of a contact hole or a trench. Here, a case in which the recess RE is in the form of a contact hole is described. However, one of ordinary skill in the art will understand that the same may be applied to a case in which the recess RE is in the form of a trench.

The substrate 110 may include a semiconductor, such as Si or Ge, or a compound semiconductor, such as SiGe, SiC, GaAs, InAs, or InP. According to some embodiments, the substrate 110 may include at least one of a group III-V material and a group IV material. The group III-V material may be a binary, ternary, or quaternary compound including at least one group III element and at least one group V element. The group III-V material may be a compound including at least one atom from among In, Ge, and Al as a group III atom and at least one atom from among As, P, and Sb as a group V atom. For example, the group III-V material may be selected from among InP, In_{z}Gal_{1-z}As (0≤z≤1) and Al_{z}Ga_{1-z} As (0≤z≤1). The binary compound may be, for example, any one of InP, GaAs, InAs, InSb, and GaSb. The ternary compound may be any one of InGaP, InGaAs, AlInAs, InGaSb, GaAsSb, and GaAsP. The group IV material may be Si or Ge. However, the group III-V material and the group IV material usable in an integrated circuit device according to the inventive concept are not limited to the above-stated examples. According to another embodiment, the substrate 110 may have a silicon-on-insulator (SOI) structure. The substrate 110 may include a conductive region, e.g., a well doped with an impurity or a structure doped with an impurity.

The plurality of active regions AC may be defined by a plurality of device isolation regions 112 formed on the substrate 110. A device isolation region 112 may include a silicon oxide layer, a silicon nitride layer, a silicon oxynitride layer, or a combination thereof.

The interlayer insulation layer 120 may include a silicon oxide layer.

Referring to FIG. 5B, a barrier metal material layer 122m is formed inside the recess RE and on the entire top surface of the interlayer insulation layer 120. The barrier metal material layer 122m may be formed through atomic layer deposition (ALD), chemical vapor deposition (CVD), or physical vapor deposition (PVD). The barrier metal material layer 122m may include, for example, Ti and/or TiN.

Also, a conductive material layer 124m may be formed on the entire top surface of the barrier metal material layer 122m. The conductive material layer 124m may include a metal, such as Cu, and may be formed through CVD.

Referring to FIG. 5C, CMP may be performed on the conductive material layer 124m to limit the conductive material layer 124m to the inside of the recess RE. To this end, the CMP slurry composition of the inventive concept as described above may be used, and the CMP slurry composition may include an organic booster containing an amino acid, a pH adjuster, inorganic abrasive particles of less than 0.1 weight %, and DIW. Here, the CMP slurry composition may be substantially free of the inorganic abrasive particles.

At this time, CMP may be performed by using the barrier metal material layer 122m as a polishing stop film.

Referring to FIG. 5D, by performing CMP on the barrier metal material layer 122m that is exposed, the barrier metal layer 122 may be defined within respective contact holes and complete node separation between the contact holes may be performed. To this end, a CMP slurry composition as described above may be used.

In the process described with reference to FIG. 5D, as in the process described with reference to FIG. 5C, polishing may be performed without inorganic abrasive particles in the CMP slurry composition.

Although FIGS. 5C and 5D show that CMP is performed in two stages by respectively using the barrier metal material layer 122m and the interlayer insulation film 120 as polishing stop films, according to some embodiments, CMP may be performed in a single stage by utilizing only the interlayer insulation layer 120 as a polishing stop film.

Also, the CMP slurry composition may be adjusted to have a pH concentration from about 7 to about 9, but the range of the pH concentration may be adjusted as needed. The range of the pH concentration may be controlled by changing the content of a pH adjuster.

The plurality of conductive regions 124 may be connected to one terminal of a switching device, such as a field effect transistor, formed on the substrate 110. The plurality of conductive regions 124 may include doped polysilicon, a metal, a conductive metal nitride, a metal silicide, or a combination thereof but are not limited to the above-stated examples.

Referring to FIG. 5E, an insulation layer 128 covering the interlayer insulation layer 120 and the plurality of conductive regions 124 is formed. The insulation layer 128 may be used as an etch stop layer.

The insulation layer 128 may include an insulation material having an etch selectivity with respect to the interlayer insulation layer 120 and a mold layer 130 (refer to FIG. 5F) formed in a subsequent process.

Referring to FIG. 5F, the mold layer 130 is formed on the insulation layer 128.

According to some embodiments, the mold layer 130 may include an oxide layer. For example, the mold layer 130 may include boro phospho silicate glass (BPSG), phosphor silicate glass (PSG), undoped silicate glass (USG), spin on dielectric (SOD), and an oxide film formed through high density plasma chemical vapor deposition (HDP CVD). A thermal CVD process or a plasma CVD process may be used to form the mold layer 130.

According to some embodiments, the mold layer 130 may include a supporting layer. The supporting layer may include a material having an etching selectivity with respect to the mold layer 130. The supporting layer may include a material having a relatively low etching rate with respect to an etching atmosphere used when removing the mold film 130 in a subsequent process, e.g., an etchant containing ammonium fluoride (NH₄F), hydrofluoric acid (HF), and DIW. According to some embodiments, the supporting layer may include silicon nitride, silicon carbide nitride, tantalum oxide, titanium oxide, or a combination thereof, but the material constituting the supporting layer is not limited to the above-stated examples.

Referring to FIG. 5G, a sacrificial layer 142 and a mask pattern 144 are sequentially formed on the mold layer 130.

The sacrificial layer 142 may include BPSG, PSG, USG, SOD, or an oxide layer formed through a HDP CVD process. The sacrificial layer 142 may have a thickness from about 50 nm to about 200 nm. The sacrificial layer 142 may protect the supporting layer included in the mold layer 130.

The mask pattern 144 may include an oxide layer, a nitride layer, a polysilicon layer, a photoresist layer, or a combination thereof. A region in which a lower electrode of a capacitor is to be formed may be defined by the mask pattern 144.

Referring to FIG. 5H, the sacrificial layer 142 and the mold layer 130 are dry etched by using the mask pattern 144 as an etching mask and using the insulation layer 128 as an etch stop layer, thereby forming a sacrificial pattern 142P and a mold pattern 130P defining a plurality of holes H1.

In this case, the insulation layer 128 may also be etched by over-etching, and thus, an insulation pattern 128P exposing the plurality of conductive regions 124 may be formed by the over-etching.

Referring to FIG. 5I, after the mask pattern 144 is removed from a result structure of FIG. 5H, a lower electrode forming conductive layer 150 covering the inner sidewalls of the plurality of holes H1, an exposed surface of the insulation pattern 128P, surfaces of the plurality of conductive regions 124 respectively exposed inside the plurality of holes H1, and an exposed surface of the sacrificial pattern 142P is formed.

The lower electrode forming conductive layer 150 may be conformally formed on sidewalls of the plurality of holes H1, such that the inner space of each of the plurality of holes H1 partially remains.

According to some embodiments, the lower electrode forming conductive layer 150 may include a doped semiconductor, a conductive metal nitride, a metal, a metal silicide, a conductive oxide, or a combination thereof. For example, the lower electrode forming conductive layer 150 may include TIN, TiAlN, TaN, TaAlN, W, WN, Ru, RuO₂, SrRuO₂, Ir, IrO₂, Pt, PtO, SRO (SrRuO₃), BSRO((Ba,Sr)RuO₃), CRO(CaRuO₃), LSCO((La,Sr)CoO₃), or a combination thereof, but the material constituting the lower electrode forming conductive layer 150 is not limited to the above-stated examples.

To form the lower electrode forming conductive layer 150, a CVD process, a metal organic CVD (MOCVD) process, or an ALD process may be used. Thereafter, although not shown in FIG. 5I, a sacrificial layer may be further formed to fill the inside of a recess defined by the lower electrode forming conductive layer 150. The sacrificial layer may cover the top surface of the lower electrode forming conductive layer 150.

Referring to FIG. 5J, the upper portion of the lower electrode forming conductive layer 150 is partially removed, thereby separating the lower electrode forming conductive layer 150 into a plurality of lower electrodes LE.

To form the plurality of lower electrodes LE, an etchback process or a CMP process may be performed to remove a portion of the upper portion of the lower electrode forming conductive layer 150 and the sacrificial pattern 142P (refer to FIG. 5I) so that the top surface of the mold pattern 130P is exposed.

The plurality of lower electrodes LE may penetrate through the insulation pattern 128P and be connected to the conductive region 124.

Referring to FIG. 5K, the mold pattern 130P is removed to expose outer wall surfaces of the plurality of lower electrodes LE having a cylindrical shape.

The mold pattern 130P may be removed through a lift-off process using an etchant.

Referring to FIG. 5L, a dielectric layer 160 is formed on the plurality of lower electrodes LE.

The dielectric layer 160 may be formed to conformally cover exposed surfaces of the plurality of lower electrodes LE.

The dielectric layer 160 may be formed through an ALD process.

The dielectric layer 160 may include an oxide, a metal oxide, a nitride, or a combination thereof. According to some embodiments, the dielectric layer 160 may include a ZrO₂ layer. For example, the dielectric layer 160 may include a single ZrO₂ layer or a multi-layer including a combination of at least one ZrO₂ layer and at least one Al₂O₃ layer.

Referring to FIG. 5M, an upper electrode UE is formed on the dielectric layer 160.

The lower electrode LE, the dielectric layer 160, and the upper electrode UE may constitute a capacitor 170.

The upper electrode UE may include a doped semiconductor, a conductive metal nitride, a metal, a metal silicide, a conductive oxide, or a combination thereof. For example, the upper electrode UE may include TiN, TiAlN, TaN, TaAlN, W, WN, Ru, RuO₂, Ir, IrO₂, Pt, PtO, SRO(SrRuO₃), BSRO((Ba,Sr)RuO₃), CRO(CaRuO₃), LSCO ((La,Sr)CoO₃), or a combination thereof, but the material constituting the upper electrode UE is not limited to the above-stated examples.

To form the upper electrode UE, a CVD, MOCVD, PVD, or ALD process may be used.

A method of manufacturing an integrated circuit device including an operation of forming the dielectric layer 160 covering surfaces of cylindrical lower electrodes LE has been described above with reference to FIGS. 5A to 5M, but the inventive concept is not limited thereto. For example, a pillar-type lower electrode having no inner space may be formed instead of the cylindrical lower electrode LE, and the dielectric layer 160 may be formed on the pillar-shaped lower electrode.

According to the method of manufacturing a semiconductor device according to embodiments described with reference to FIGS. 5A to 5M, to form the barrier metal layer 122m and the conductive region 124, CMP is performed by using a CMP slurry composition according to the inventive concept. However, one of ordinary skill in the art will understand that CMP may also be performed by using the CMP slurry composition according to embodiments to manufacture other semiconductor devices. The CMP slurry composition used to manufacture the semiconductor device may have the same composition as the CMP slurry composition described above.

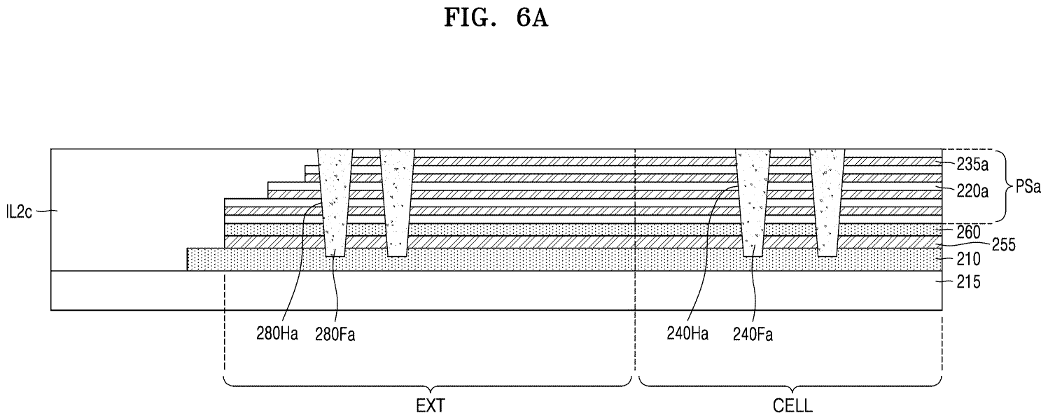

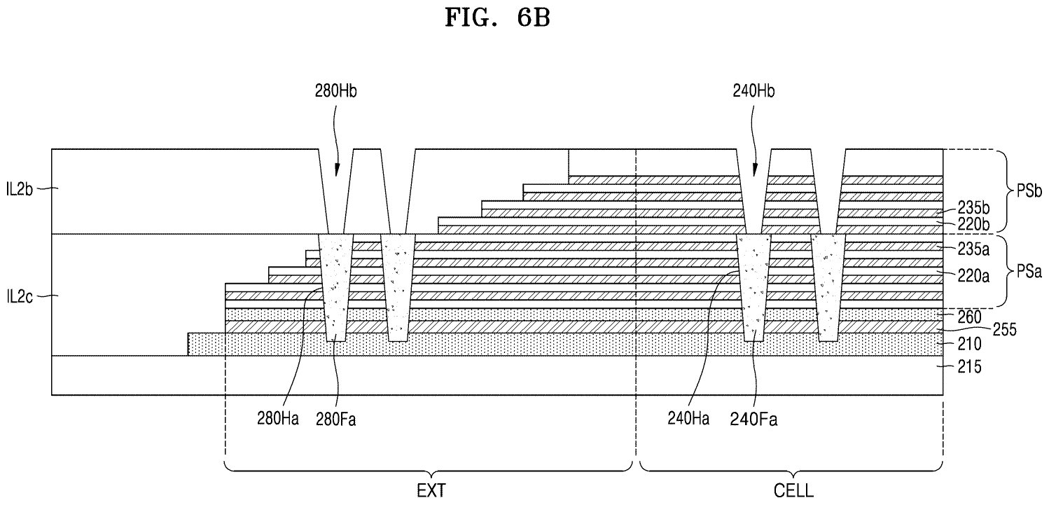

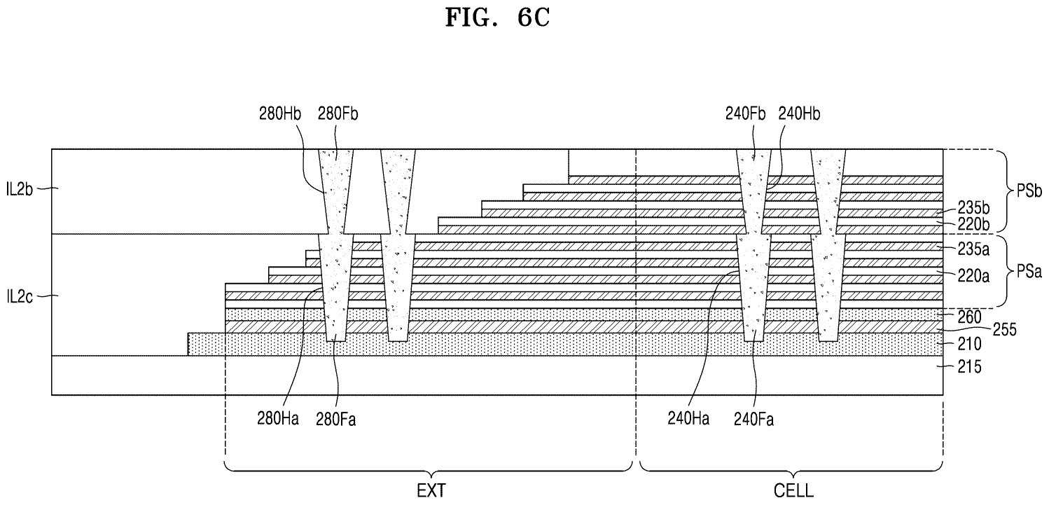

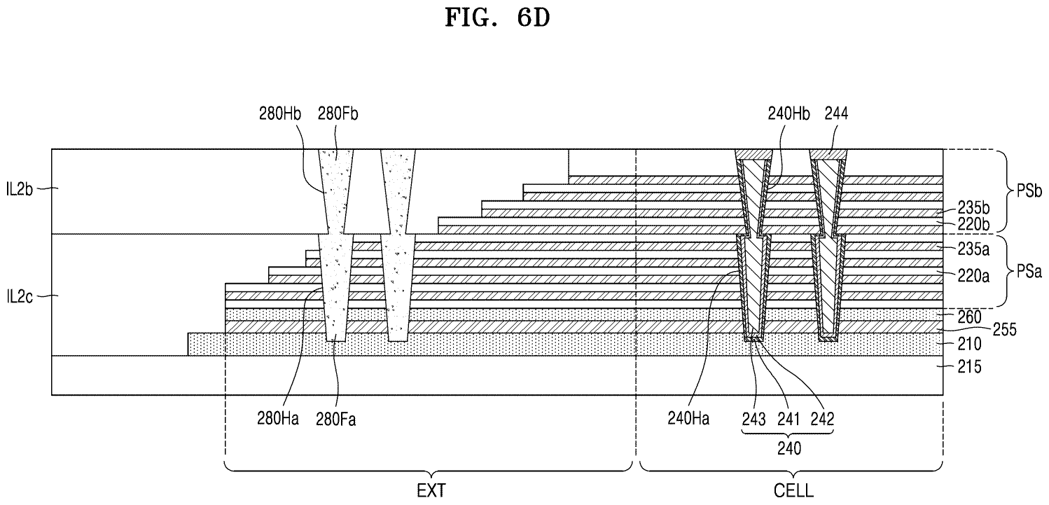

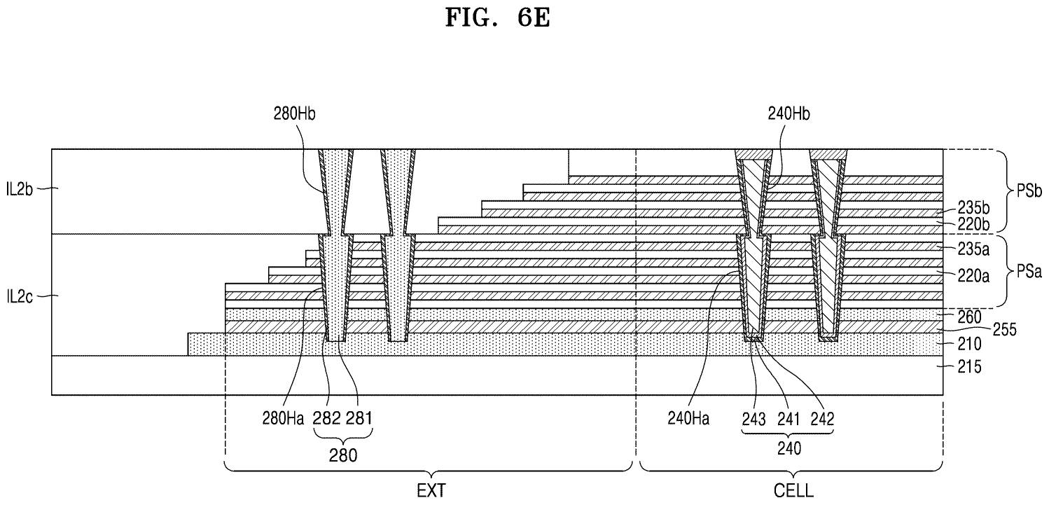

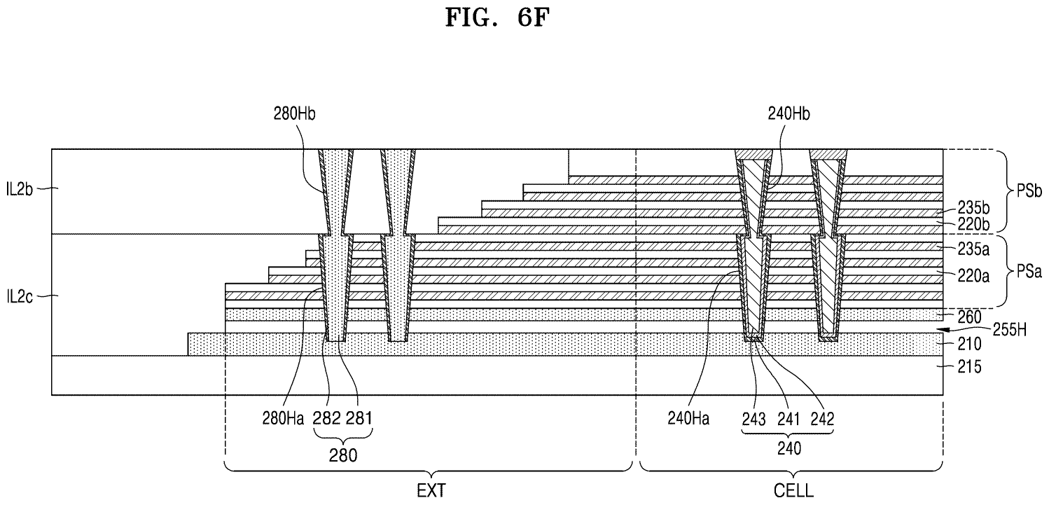

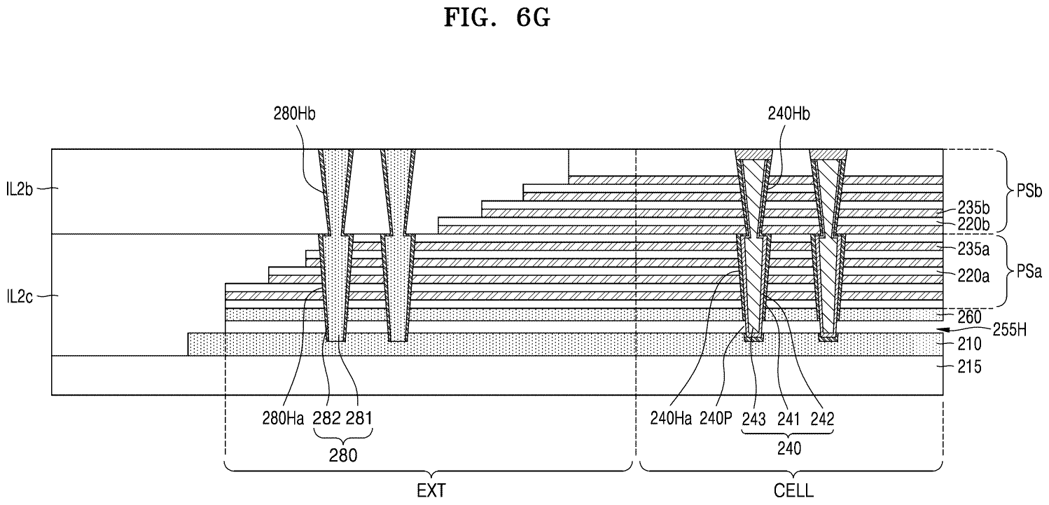

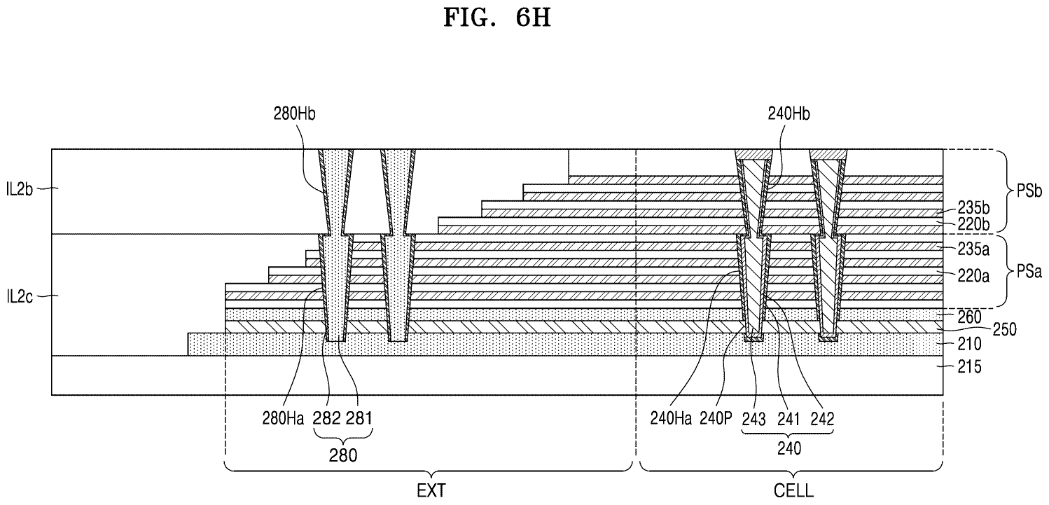

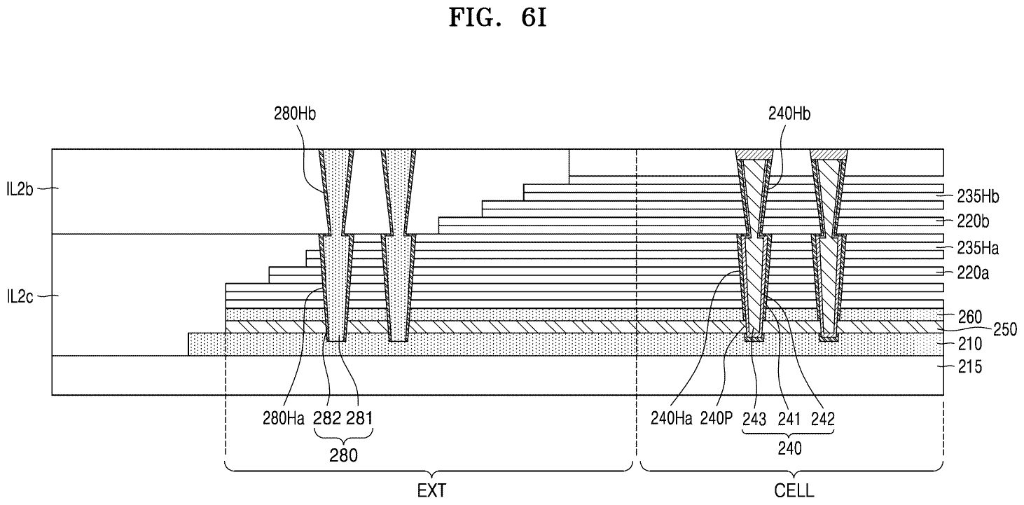

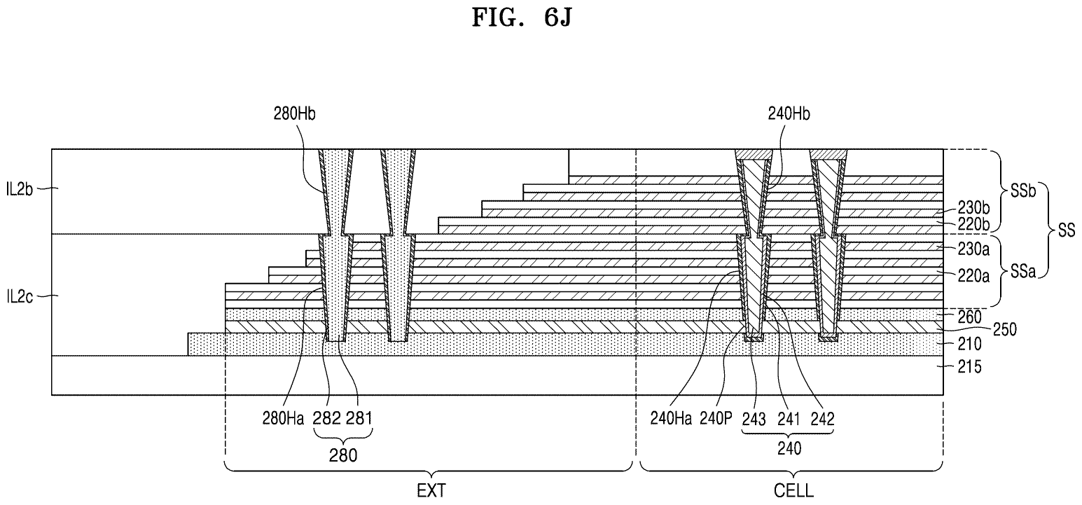

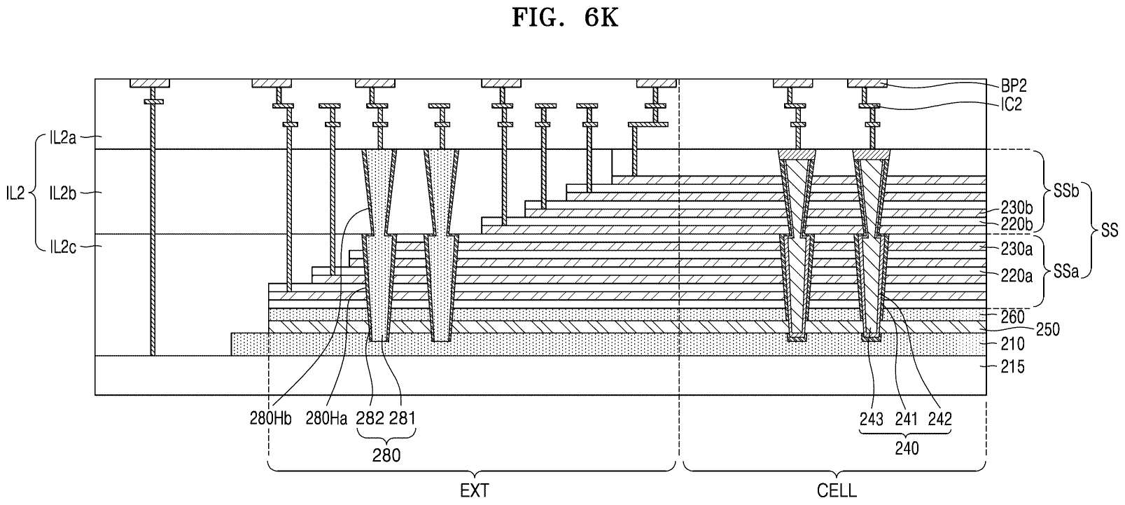

FIGS. 6A to 6K are side cross-sectional views sequentially showing a method of manufacturing a semiconductor device 200, according to another embodiment.

Referring to FIG. 6A, a substrate 215 may be provided. The substrate 215 may include, for example, a semiconductor material, such as a group IV semiconductor material, a group III-V semiconductor material, or a group II-VI semiconductor material. A common source line layer 210 may be formed on the substrate 215. A first portion PSa of the preliminary stacked structure may be formed on the common source line layer 210. The first portion Psa of the preliminary stacked structure may be formed by alternately forming a plurality of first interlayer insulation layers 220a and a plurality of first sacrificial layers 235a on the common source line layer 210. Each first sacrificial layer 235a may each include a material having an etch selectivity with respect to each first interlayer insulation layer 220a. For example, when the first interlayer insulation layer 220a includes silicon oxide, the first sacrificial layer 235a may include silicon nitride.

In some embodiments, a lower sacrificial layer 255 may be further formed between the common source line layer 210 and the first portion Psa of the preliminary stacked structure. According to some embodiments, a lower support layer 260 may be further formed between the lower sacrificial layer 255 and the first portion Psa of the preliminary stacked structure. The lower sacrificial layer 255 may include a material having an etch selectivity with respect to the common source line layer 210 and the lower support layer 260. For example, when the common source line layer 210 and the lower support layer 260 include polysilicon, the lower sacrificial layer 255 may include silicon nitride.

The first portion Psa of the preliminary stacked structure may be patterned to have a stepped region EXT. Next, a first portion IL2c of an insulation structure may be formed on the substrate 215 and the first portion Psa of the preliminary stacked structure. Next, a first channel hole 240Ha penetrating through a cell region CELL of the first portion Psa of the preliminary stacked structure and a first dummy channel hole 280Ha penetrating through the stepped region EXT of the first portion Psa of the preliminary stacked structure may be formed. The first dummy channel hole 280Ha may further penetrate through the first portion IL2c of the insulation structure. The first channel hole 240Ha and the first dummy channel hole 280Ha may further penetrate through the lower support layer 260 and the lower sacrificial layer 255.

Next, the first channel hole 240Ha and the first dummy channel hole 280Ha are filled with a first filling layer 240Fa and a first dummy filling layer 280Fa, respectively. The first filling layer 240Fa and the first dummy filling layer 280Fa may include polysilicon according to some embodiments.

To form the first filling layer 240Fa and the first dummy filling layer 280Fa, polysilicon may be formed on the uppermost first interlayer insulation layer 220a as well as inside the first channel hole 240Ha and the first dummy channel hole 280Ha. Thereafter, by performing CMP using the top surface of the first interlayer insulation layer 220a as a polishing stop film, polysilicon may be confined to the insides of the first channel hole 240Ha and the first dummy channel hole 280Ha. When performing the CMP, the depth of a recess formed may be effectively controlled by using the CMP slurry composition according to the inventive concept.

Referring to FIG. 6B, a second portion PSb of the preliminary stacked structure may be formed on the first portion Psa of the preliminary stacked structure. The second portion PSb of the preliminary stacked structure may be formed by alternately forming a plurality of second interlayer insulation layers 220b and a plurality of second sacrificial layers 235b on the first portion Psa of the preliminary stacked structure. Each second sacrificial layer 235b may include a material having an etch selectivity with respect to each second interlayer insulation layer 220b. For example, when the second interlayer insulation layer 220b includes silicon oxide, the second sacrificial layer 235b may include silicon nitride.

Next, the second portion PSb of the preliminary stacked structure may be patterned to have a stepped region EXT. Next, a second portion IL2b of the insulation structure may be formed on the first portion iL2c of the insulation structure and the first portion Psa and the second portion PSb of the preliminary stacked structure. Next, a second channel hole 240Hb penetrating through the second portion PSb of the preliminary stacked structure and exposing the first filling layer 240Fa and a second dummy channel hole 280Hb penetrating through the second portion IL2b of the insulation structure and exposing the first dummy filling layer 280Fa may be formed.

Referring to FIG. 6C, the second channel hole 240Hb and the second dummy channel hole 280Hb may be filled with a second filling layer 240Fb and a second dummy filling layer 280Fb, respectively. According to some embodiments, the second filling layer 240Fb and the second dummy filling layer 280Fb may include polysilicon.

To form the second filling layer 240Fb and the second dummy filling layer 280Fb, polysilicon may be formed on the uppermost layer of the second portion PSb as well as inside the second channel hole 240Hb and the second dummy channel hole 280Hb. Thereafter, by performing CMP by using the uppermost layer as a polishing stop film, polysilicon may be confined to the insides of the second channel hole 240Hb and the second dummy channel hole 280Hb. When performing the CMP, the depth of a recess formed may be effectively controlled by using the CMP slurry composition according to the inventive concept.

Referring to FIGS. 6C and 6D, the first dummy filling layer 280Fa and the second dummy filling layer 280Fb may be removed from the first dummy channel hole 280Ha and the second dummy channel hole 280Hb, respectively. According to some embodiments, to prevent the channel structure 240 from being removed, a mask that covers the channel structure 240 and exposes the second dummy filling layer 280Fb may be formed before removing the first dummy filling layer 280Fa and the second dummy filling layer 280Fb. The mask may be removed after the first dummy filling layer 280Fa and the second dummy filling layer 280Fb are removed.

Next, a dummy channel structure 280 may be formed in the first dummy channel hole 280Ha and the second dummy channel hole 280Hb. First, an insulation layer 282 may be formed on sidewalls of the first dummy channel hole 280Ha and the second dummy channel hole 280Hb. For example, the insulation layer 282 may be formed on the top surface of the second portion IL2b of the second insulation structure, the sidewall of the second dummy channel hole 280Hb, and the sidewall and the bottom surface of the first dummy channel hole 280Ha, and the insulation layer 282 may be anisotropically etched, thereby removing portions of the insulation layer 282 on the top surface of the second portion IL2b of the second insulation structure and the bottom surface of the first dummy channel hole 280Ha. Next, a conductive layer 281 may be formed on the insulation layer 282. The conductive layer 281 may be formed to fill the first dummy channel hole 280Ha and the second dummy channel hole 280Hb together with the insulation layer 282.

Referring to FIGS. 6E and 6F, a space 255H may be formed between the common source line layer 210 and the lower support layer 260 by removing the lower sacrificial layer 255. A gate insulation layer 241 of the channel structure 240 and the insulation layer 282 of the dummy channel structure 280 may be exposed in the space 255H. To remove the lower sacrificial layer 255, although not shown in FIGS. 6E and 6F, a word line cut penetrating through the first portion Psa and the second portion PSb of the preliminary stacked structure and the lower support layer 260 and exposing the lower sacrificial layer 255 may be formed before removing the lower sacrificial layer 255. An etchant may reach the lower sacrificial layer 255 through the word line cut and etch the lower sacrificial layer 255.

Referring to FIGS. 6F and 6G, a portion of the gate insulation layer 241 of the channel structure 240 exposed in the space 255H may be removed to form an opening 240P penetrating through the gate insulation layer 241. The channel layer 242 may be exposed in the space 255H through the opening 240P. According to some embodiments, the thickness of the insulation layer 282 of the dummy channel structure 280 may be sufficient to prevent the conductive layer 281 from being exposed in the space 255H even when the insulation layer 282 of the dummy channel structure 280 is exposed to the etchant for removing the gate insulation layer 241 of the channel structure 240. According to another embodiment, the insulation layer 282 of the dummy channel structure 280 may be exposed to an etchant for removing a portion of the gate insulation layer 241 of the channel structure 240 and an exposed portion of the insulation layer 282 may be etched, thereby exposing the conductive layer 281 in the space 255H.

Referring to FIGS. 6G and 6H, a lower conductive layer 250 may be formed in the space 255H. The lower conductive layer 250 may contact the channel layer 242 through the opening 240P. According to some embodiments, the lower conductive layer 250 may not be in contact with the conductive layer 281. Unlike shown in FIG. 3H, according to some embodiments, the lower conductive layer 250 may penetrate through the insulation layer 282 and contact the conductive layer 281.

Referring to FIGS. 6H and 6I, a plurality of spaces 235Ha and 235Hb between the first interlayer insulation layer 220a and the second interlayer insulation layer 220b may be formed by removing the first sacrificial layer 235a and the second sacrificial layer 235b.

Referring to FIGS. 6I and 6J, a plurality of gate layers 230a and 230b may be formed in the spaces 235Ha and 235Hb between the first interlayer insulation layer 220a and the second interlayer insulation layer 220b, respectively. Therefore, the stacked structure SS including the first portion Ssa, which includes the first interlayer insulation layers 220a and the first gate layers 230a alternately stacked on the common source line layer 210, and the second portion SSb, which penetrates through the second interlayer insulation layers 220b and the second gate layers 230b alternately stacked on the first portion Ssa, may be formed.

Referring to FIG. 6K, a third portion IL2a of an insulation structure IL2, an interconnect structure IC2, and a plurality of bonding pads BP2 may be formed. Therefore, the insulation structure IL2 including the first portion IL2c, the second portion IL2b, and the third portion IL2a may be completed.

While the inventive concept has been particularly shown and described with reference to embodiments thereof, it will be understood that various changes in form and details may be made therein without departing from the spirit and scope of the following claims.

What is claimed is:

1. A chemical mechanical polishing (CMP) slurry composition comprising:
an organic booster comprising an amino acid;
a pH adjuster; and
inorganic abrasive particles of less than 0.1 weight % with respect to a total weight of the CMP slurry composition,
wherein a material constituting a remaining part of the CMP slurry composition is deionized water (DIW).

2. The CMP slurry composition of claim 1, wherein the pH adjuster is provided at an amount such that a pH concentration of the CMP slurry composition is maintained within a range from about 7 to about 9.

3. The CMP slurry composition of claim 1, wherein a content of the organic booster is within a range from about 10 ppm to about 20000 ppm.

4. The CMP slurry composition of claim 1, wherein the organic booster comprises at least one selected from a group consisting of leucine, tryptophan, tyrosine, and phenylalanine.

5. The CMP slurry composition of claim 1, wherein the CMP slurry composition is configured to etch a protrusion of a copper (Cu) film.

6. The CMP slurry composition of claim 5, wherein a height of the protrusion does not exceed 200 Å.

7. The CMP slurry composition of claim 1, wherein the CMP slurry composition is capable of adjusting a static etch rate of a metal layer and a removal rate of the metal layer.

8. A chemical mechanical polishing (CMP) slurry composition comprising:
deionized water (DIW);
an organic booster comprising an amino acid; and
a pH adjuster,
wherein the CMP slurry composition is substantially free of inorganic abrasive particles.

9. The CMP slurry composition of claim 8, wherein the pH adjuster is provided at an amount such that a pH concentration of the CMP slurry composition is maintained within a range from about 7 to about 9.

10. The CMP slurry composition of claim 8, wherein a content of the organic booster is within a range from about 10 ppm to about 20000 ppm.

11. The CMP slurry composition of claim 8, wherein the organic booster comprises at least one selected from a group consisting of leucine, tryptophan, tyrosine, and phenylalanine.

12. The CMP slurry composition of claim 8, wherein the CMP slurry composition is configured to etch a protrusion of a copper (Cu) film.

13. The CMP slurry composition of claim 12, wherein a height of the protrusion does not exceed 200 Å.

14. The CMP slurry composition of claim 8, wherein the CMP slurry composition is capable of adjusting a static etch rate of a metal layer and a removal rate of the metal layer.

15. A method of manufacturing a semiconductor device, the method comprising:
forming, on a substrate, an insulation pattern including a plurality of openings spaced apart from one another in a horizontal direction;
forming a metal layer in the plurality of openings of the insulation pattern; and
chemical mechanical polishing the metal layer on a polishing pad by using a chemical mechanical polishing (CMP) slurry composition by using the insulation pattern as a polishing stop film,
wherein the CMP slurry composition comprises an organic booster containing an amino acid, a pH adjuster, and inorganic abrasive particles of less than 0.1 weight % with respect to a total weight of the CMP slurry composition, and a material constituting a remaining portion of the CMP slurry composition is deionized water (DIW).

16. The method of claim 15, wherein the CMP slurry composition is devoid of inorganic abrasive particles.

17. The method of claim 15, wherein the metal layer comprises copper (Cu), and
the CMP slurry composition etches a protrusion having a height not exceeding 200 Å, with respect to the metal layer.

18. The method of claim 15, wherein the pH adjuster is provided at an amount such that a pH concentration of the CMP slurry composition is maintained within a range from about 7 to about 9, and
the organic booster is included within a range from about 10 ppm to about 20000 ppm.

19. The method of claim 15, wherein the organic booster comprises at least one selected from a group consisting of leucine, tryptophan, tyrosine, and phenylalanine.

20. The method of claim 15, wherein a static etch rate of the metal layer and a removal rate of the metal layer are adjustable.
